(19) United States
(12) Patent Application Publication
(10) Pub. No.: US 2021/0210462 A1
(43) Pub. Date: Jul. 8, 2021

(54) CHIP SCALE PACKAGE WITH REDISTRIBUTION LAYER INTERRUPTS

(71) Applicant: Texas Instruments Incorporated, Dallas, TX (US)

(72) Inventors: Vivek Swaminathan Sridharan, Dallas, TX (US); Enis Tuncer, Dallas, TX (US); Christopher Daniel Manack, Flower Mound, TX (US); Patrick Francis Thompson, Allen, TX (US)

(21) Appl. No.: 16/734,836

(22) Filed: Jan. 6, 2020

(51) Int. Cl. H01L 23/00

(52) U.S. Cl. CPC H01L 24/95; H01L 24/05; H01L 2224/02333; H01L 24/81; H01L 24/13

(57) ABSTRACT

A semiconductor device includes a semiconductor surface having circuitry with metal interconnect layers over the semiconductor surface including a selected metal interconnect layer providing an interconnect trace having a first and second end. A top dielectric layer is on the top metal interconnect layer. A redistribution layer (RDL) is on the top dielectric layer. A corrosion interruption structure (CIS) including the interconnect trace bridges an interrupting gap in a trace of the RDL.

### FIELD

This Disclosure relates to chip-scale semiconductor packages.

### BACKGROUND

A wafer chip scale package (WCSP) is a type of integrated circuit (IC) package. The needed metal interconnect and dielectric layers are applied on top of a wafer using photolithographic techniques that fit well with wafer processing. These layers are typically thin, and a semiconductor die generally forms a major portion of the package body. All of the interconnects between the semiconductor die, the package, and the user's printed circuit board (PCB) are on the active side (top side) of the semiconductor die.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed aspects recognize although copper is conventionally used as a redistribution layer (RDL) in WCSP's including for solder bump pads due to its superior electrical and thermal properties, copper readily oxidizes when the protective passivation layer that is over the copper RDL is compromised, such as by passivation layer cracking. Passivation cracking can occur during highly accelerated reliability temperature and humidity stress testing (BHAST/uHAST) after pre-conditioning the WCSP. This accelerated testing simulates copper corrosion (or corrosion of other metals prone to corrosion), dendritic/non-dendritic crystal growth which can cause leakage, and cracking that can occur during conventional semiconductor package assembly and aging over the WCSP's lifetime while operating in the field. Passivation cracking during assembly can also occur during solder reflow, which may be performed at about 240° C. to 250° C. for about a minute, that takes place for the WCSP after flipchip placing the WCSP onto land pads of a PCB.

Disclosed aspects include a semiconductor device, such as a WCSP, including a semiconductor surface having circuitry with metal interconnect layers over the semiconductor surface including a selected metal interconnect layer providing an interconnect trace having a first and second end. A top dielectric layer is on the top metal interconnect layer. A RDL is on the top dielectric layer. A corrosion interruption structure (CIS) including the interconnect trace bridges an interrupting gap in a trace of the RDL.

The CIS generally includes a first side of the RDL connecting to first metal plugs on the first end of the trace, an interrupting gap in the RDL over the interconnect trace, and a second side of the RDL connecting to second metal plugs on the second end of the interconnect trace. The interconnect trace generally has a length that is longer than a length of the interrupting gap, which together with the first metal plugs and the second metal plugs provide a coupling path across the interrupting gap.

### BRIEF DESCRIPTION OF THE DRAWINGS

Reference will now be made to the accompanying drawings, which are not necessarily drawn to scale, wherein:

FIG. 1A depicts a cross-sectional view of a conventional WCSP having RDL corrosion resulting from a passivation layer crack, where the RDL lacks a disclosed CIS.

FIG. 1B depicts a cross-sectional view of an example WCSP having RDL corrosion resulting from the passivation layer crack shown in FIG. 1A, where the RDL includes a disclosed CIS that can be seen to be limiting the area coverage of the corrosion.

FIG. 2A and FIG. 2B depict a top view of a disclosed CIS positioned at different proximate positions in an RDL trace that is coupled to a bump pad of the RDL, having an under bump metallization (UBM) layer thereon.

FIG. 3 depicts an example WCSP including a disclosed CIS in the RDL of a ground ring that surrounds a plurality of bump pads, where there are CIS positioned at every bump pad pitch.

FIG. 4A is a cross-sectional view of an in-process disclosed semiconductor device after forming a metal interconnect layer over a substrate having a semiconductor surface layer, where the metal interconnect layer includes a trace used for the CIS, after depositing a top dielectric layer, and after forming metal plugs in the top dielectric layer including a plurality of metal plugs connecting to the trace. FIG. 4B is a cross-sectional view of an in-process semiconductor device after forming a patterned RDL on a seed or barrier layer that is on the top dielectric layer, the RDL including at least one contact pad and at least one interrupting gap, showing the trace having a length that is longer than the interrupting gap for providing a coupling path across the gap. FIG. 4C is a cross-sectional view of an in-process semiconductor device after forming a patterned passivation layer including openings including for bump pads in a passivation layer. FIG. 4D is a cross-sectional view of an in-process semiconductor device after forming a UBM layer. FIG. 4E is a cross-sectional view of an in-process semiconductor device after solder ball attach to the UBM layer.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this Disclosure.

Disclosed aspects recognize copper is prone to corrosion (also termed “oxidation”), and can then undergo electrolytic dissolution when the passivation layer on top of a copper RDL is compromised (e.g., cracked). Cracking can occur due to being exposed to moisture, and/or contaminants such as chlorine and potassium which may be present in solder fluxes, underfill, and flux cleaners, particularly when the WCSP is at an elevated temperature. Common reasons for metal corrosion of the RDL include a passivation layer (e.g., a polyimide (PI)) crack near the UBM, and a scribe seal crack. The scribe seal is part of the scribe street which is where wafer singulation (mechanically sawn or laser sawn) takes place, and a scribe seal is positioned on either side of the scribe street which becomes part of adjacent semiconductor chips after singulation. The scribe seal is designed to prevent saw induced crystal cracks from extending into vulnerable areas of the semiconductor chip having circuitry.

Moreover, when a scribe seal crack occurs that results in a crack in the top layer inter-layer dielectric (ILD) and/or passivation layer that is over the top layer ILD even in the scribe seal area, despite there generally not being any RDL in the scribe seal area, the RDL adjacent to the dielectric layer in the scribe seal can still corrode. This RDL corrosion can begin with the corrosion of the top level interconnect metal such as comprising aluminum or copper, which in the case of aluminum when exposed is known to galvanically react to copper, such as with a copper RDL that is proximately located.

Therefore, the RDL either under the cracked passivation either inside the scribe line or proximate to cracked passivation and top layer ILD in the scribe line area can corrode in the presence of moisture or a contaminant, particularly when there is sufficient voltage bias on the anode side. Bias conditions on portions of the RDL are generally present during WCSP testing, or bias conditions are present during field use of the WCSP.

Disclosed aspects recognize conventional RDL continuity promotes corrosion progression. To solve this problem, disclosed aspects provide CIS that break the RDL continuity by including at least one interrupting gap in the RDL that can be positioned at relatively high stress areas on the WCSP (e.g., near bond pads). The CIS are thus implemented during back end of the line (BEOL) wafer fabrication. CIS are realized by breaks in the RDL continuity enabled by adding metal plugs (e. g., Tungsten (W)) plugs in the ILD (generally in the top ILD) coupled to a trace in a selected metal interconnect layer, typically, but not necessarily, being the top metal interconnect layer, which are available in BEOL layers in some semiconductor process flows. Including disclosed CIS limit the area of possible metal corrosion and reduces the probability of the corrosion being present near a high voltage gradient location in the circuit that may be especially prone to metal corrosion.

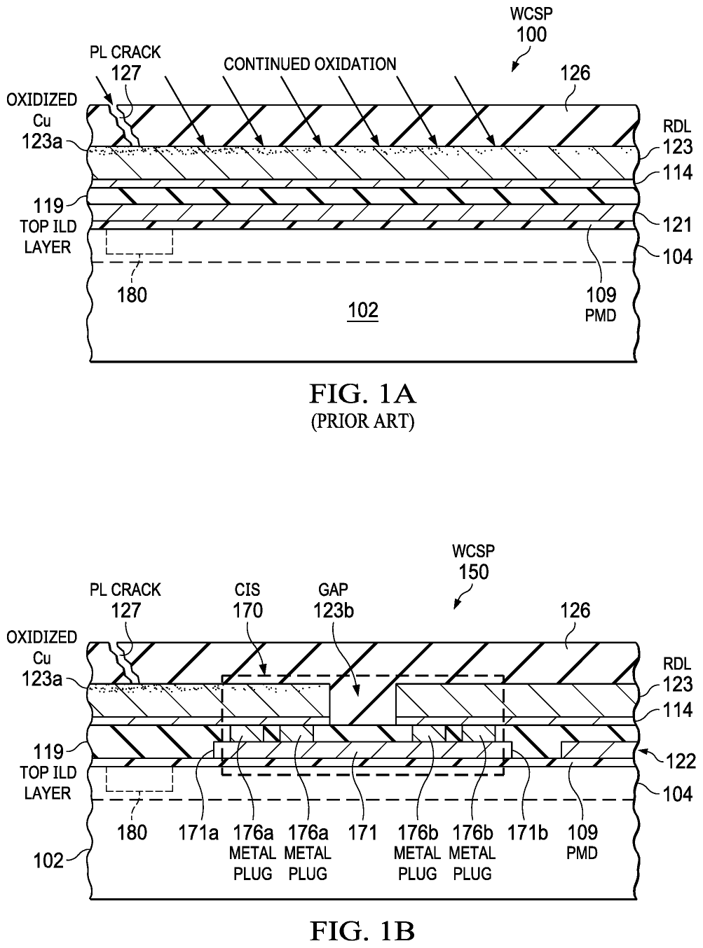

FIG. 1A depicts a cross-sectional view of a conventional WCSP 100 having corrosion in an RDL 123 resulting from a crack 127 in the passivation layer 126, where the RDL 123 of the WCSP 100 is continuous, and thus lacks a disclosed CIS. The WCSP 100 comprises a substrate 102 including a semiconductor surface layer 104 including circuitry 180 configured for at least one function. A common arrangement is where the semiconductor surface layer 104 comprises an epitaxial layer such as a silicon epitaxial layer and the substrate 102 comprises a single crystal material, such as bulk silicon. The circuitry 180 comprises circuit elements (including transistors, and generally diodes, resistors, capacitors, etc.) formed in the semiconductor surface layer 104 on the substrate 102 configured together for generally realizing at least one circuit function. Example circuit functions include analog (e.g., amplifier or power converter), radio frequency (RF), digital, or non-volatile memory functions.

There is generally a multi-layer metal stack on a pre-metal dielectric (PMD) layer 109, such as comprising silicon oxide, that is on the semiconductor surface layer 104, shown for simplicity in FIG. 1A as a top ILD layer 119 on a metal interconnect layer 121 on the PMD layer 109. There is also shown a seed layer 114 on the top ILD layer 119. The seed layer 114 in one arrangement comprises TiW. The RDL 123 is on the seed layer 114, where the RDL 123 generally comprises copper or a copper alloy.

There is a passivation layer 126, such as a polyimide layer, on the RDL 123. The passivation layer 126 can comprise polyimide in one arrangement, and can also comprise a two layer passivation. As noted above there is a crack 127 shown in the passivation layer 126. Originating from exposure to the ambient created by the crack 127, there can be copper oxidation shown as 123a of the top side of the RDL 123.

As known in the art, a RDL is the interface between the IC chip and the package for flip-chip assembly. An RDL comprises at least one extra metal layer including wiring on top of metal interconnect layers including a top metal interconnect that provides the bond pads available for the RDL bonding out at other die area locations, typically as bump pads. Bump pads are usually placed in a two-dimensional grid pattern and each one generally has two pads (one pad on the top and one pad on the bottom) that are then attached to the RDL 123 and the package substrate, typically a PCB, respectively. The RDL 123 thus serves as the layer connecting the bond pads and the bump pads.

There can be two or more layers of RDL. In the case of two layers of RDL for example, a disclosed interruption gap will generally be formed in the top RDL layer, while vertical connections will be made through a thickness of the bottom RDL layer to reach down to a metal interconnect layer, typically the top level metal interconnect layer. As noted above, the metal interconnect layer can comprise aluminum or copper that have a W plug separating them from the RDLs.

Specifically, for a 1 RDL layer structure the CIS can be implemented by a first RDL layer (RDL1) having a gap coupled on a first side of the gap to tungsten plugs coupling to a trace in a top metal interconnect layer (or goes down to lower metal interconnect layer if needed) and on a second side gap the trace coupled to tungsten plugs coupling to RDL1. For a 2 layer RDL structure, a second RDL layer (RDL2) can be interrupted with RDL2 coupled to a filled metal via through the passivation layer coupled to RDL1 that is coupled to W plugs under first side of the gap coupled to a trace in the top metal interconnect layer (or goes down to a lower metal interconnect layer if needed), with the trace on the second side of the gap coupling to W plugs coupled to RDL1, coupled through a metal via in the passivation layer to RDL2. If there is a 3 RDL layer structure, to implement a disclosed CIS one would go through RDL2 and RDL1 to a trace in the top metal interconnect layer (or a lower metal interconnect layer if needed).

FIG. 1B depicts a cross-sectional view of an example WCSP 150 having RDL corrosion 123a resulting from the passivation layer crack 127 shown in FIG. 1A, where the corrosion can be seen to be limited in its lateral progression by the interrupting gap 123b in the RDL 123 provided by a disclosed CIS 170. As with the WCSP 100 shown in FIG. 1A, below the RDL 123 there is a top ILD layer 119 on a metal interconnect layer now shown in FIG. 1B as 122 having an interconnect trace 171 that is shown that is the bottom part of the CIS 170, where the interconnect trace 171 is over PMD layer 109 which is on the semiconductor surface layer 104. The interconnect trace 171 has a first end 171a and a second end 171b. There is also again shown a seed layer 114 on the top ILD layer 119 for seeding the RDL 123 for electroplating metal, in the typical case of a copper layer for the RDL 123.

The RDL 123 generally comprises copper or a copper alloy. The interconnect trace 171 has a length that is longer than the interrupting gap 123b to enable metal plugs (e.g., W filled plugs) connections to ends of the RDL 123 with first metal plugs 176a connecting to a first side of the interrupting gap 123b and second metal plugs 176b connecting to a second side of the interrupting gap 123b. The metal plugs 176a, 176b through the top ILD layer 119 connect to respective ends of the interconnect trace 171 for providing a coupling path for the RDL 123 across the interrupting gap 123b. Typically, the metal plugs have a square cross-sectional area. However, the cross-sectional area can also be circular, each thus having a single area dimension, or can be rectangular in shape so that it has a length dimension and a width dimension. The single plug area dimension in the case of a square plug or a circular plug, or the width in the case of a rectangular metal plug, can be 0.25 μm to 10 μm.

The interrupting gap 123b of the CIS 170 also limits lateral progression of the oxidized copper 123a of the RDL 123 on the side opposite the crack 127 because catalyst or moisture diffusion is only possible opposite the crack 127 through the bulk of the passivation layer 126 which significantly limits its diffusion. The interrupting gap 123b of the CIS 170 also provides delamination resistance by arresting (stopping) delamination occurring between the passivation layer 126 and the RDL 123, which can result from oxidizing of a copper RDL.

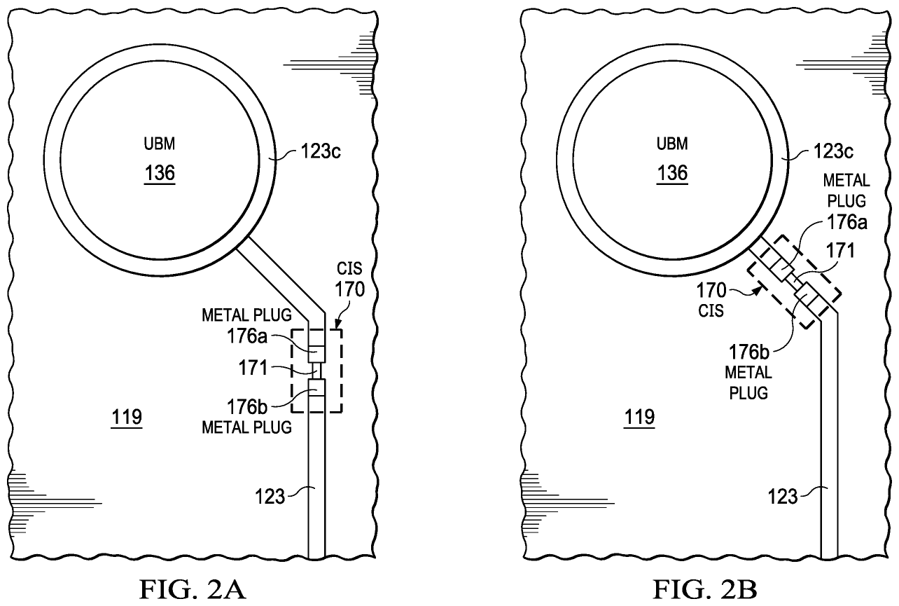

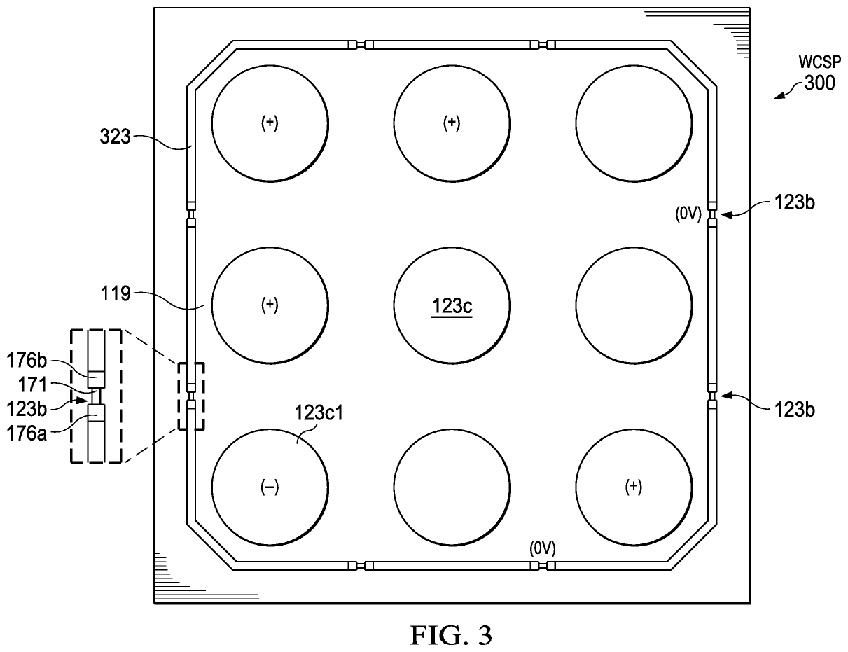

FIG. 2A and FIG. 2B depict a top view of a disclosed CIS 170 positioned at different proximate positions in an RDL trace that is coupled to a bump pad 123c of an RDL 123 having an UBM layer 136 thereon. There are metal plugs 176a and 176b coupled to ends of an interconnect trace 171 of a metal interconnect layer (other regions of the metal interconnect layer are not shown) positioned within a trace of an RDL 123 proximate to the bump pad 123c. The UBM layer 136 as known in the art provides a solderable surface, and can comprise a variety of materials including copper or gold. As used herein, ‘proximate’ to a bump pad means a distance of 0.25 to 2 times a center-to-center pitch of the bump pads in the typical case of a two-dimensional (2D) bump pad array. FIG. 3 described below depicts a 2D array of bump pads.

FIG. 3 depicts a top view of an example WCSP 300 including a CIS comprising an interruption gap 123b in the ground ring 323 comprising an RDL that is along the periphery of the WCSP 300 which surrounds the bump pads 123c. FIG. 3 also shows to the left an interconnect trace 171 having first metal plugs 176a connected to first end 171a and second metal plugs 176b connected to the second end 171b of the interconnect trace 171 (of the metal interconnect layer 122 shown in FIG. 1B), and as shown in FIG. 1B as described above the metal plugs 176a, 176b on their top side are also coupled to the RDL 123 on respective sides of the interruption gap 123b.

The ground ring 323 is shown connected at 0 V, while the bump pads 123c other than bump pad 123c1 positioned on the lower left of the bump had array are shown with a + sign indicating they are connected in normal operation to some voltage level that is above the ground potential of 0 V. The RDL For WCSP 300 provides a 2D array of bump pads 123c and the ground ring 323. The CIS are shown positioned to provide one interruption gap 123b at every bump pitch located about 0.5× a bump pitch from each bump. A conventional ground ring structure lacks any interruption gaps, and thus has a continuous RDL for the ground ring structure.

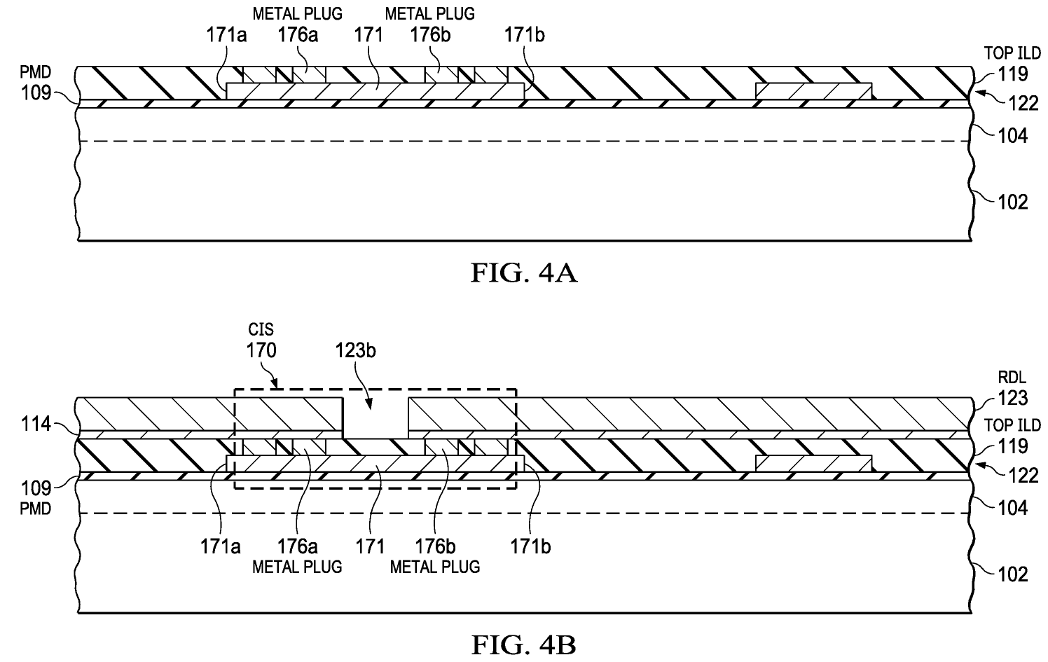

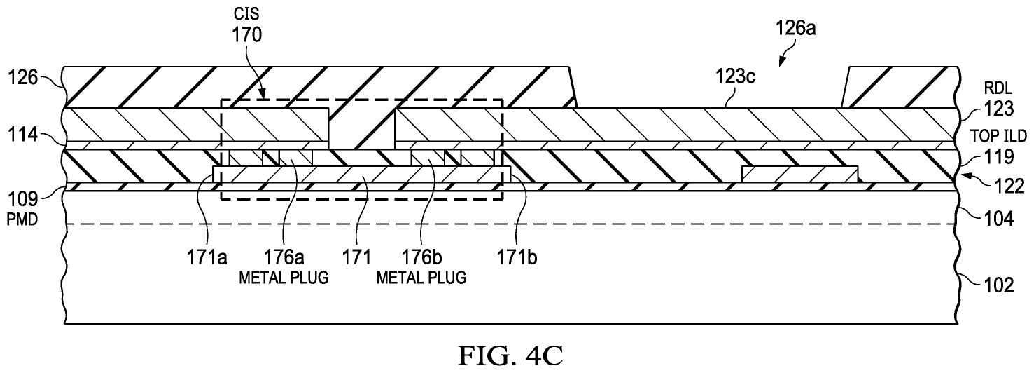

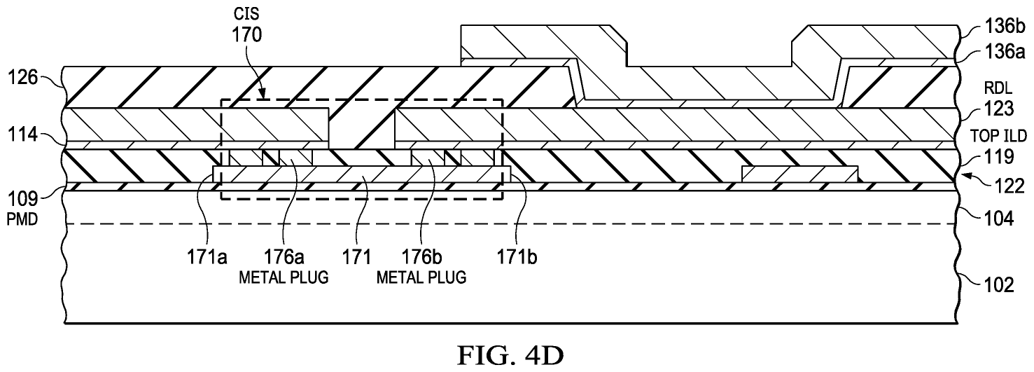

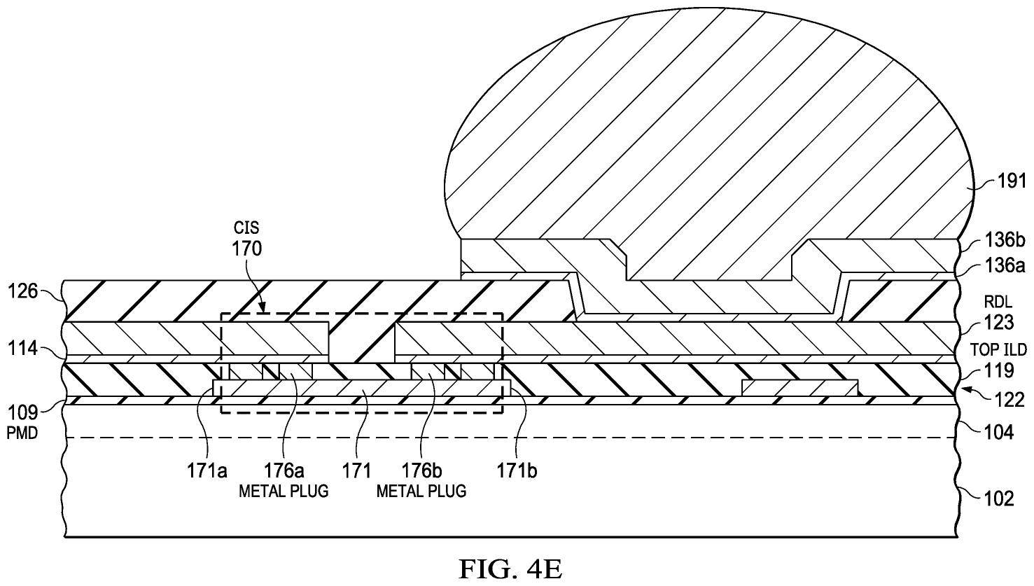

FIG. 4A is a cross-sectional view of an in-process semiconductor device, such as a WCSP, after forming a patterned metal interconnect layer over a substrate 102 having a semiconductor surface layer 104, where the metal interconnect layer 122 includes an interconnect trace 171 having a first end 171a and a second end 171b used for the CIS, after depositing a top IDL layer 119 on the PMD layer 109, and after forming metal plugs 176a, 176b in the top IDL layer 119 including a plurality of metal plugs connecting to the first end 171a of the interconnect trace 171 and to the second end 171b of the interconnect trace 171. The circuitry 180 formed in the semiconductor surface layer 104 shown in FIG. 1B that is formed before the deposition of the top ILD 119 shown in FIG. 4A is not shown in FIGS. 4A-4F for simplicity.

FIG. 4B is a cross-sectional view of an in-process semiconductor device after forming a patterned RDL 123 on a seed layer 114 on the top ILD layer 119 to complete a CIS 170, with the RDL 123 including at least one interrupting gap 123b, showing its interconnect trace 171 having a length that is longer than the interrupting gap 123b together with the metal plugs 176a, 176b for providing a coupling path across the interrupting gap 123b. FIG. 4C is a cross-sectional view of an in-process semiconductor device after forming a patterned passivation layer 126 including openings shown as a passivation aperture 126a for exposing a bump pad 123c. FIG. 4D is a cross-sectional view of an in-process semiconductor device after forming a UBM layer stack comprising upper UBM layer 136b on a lower UBM layer 136a, that generally also includes a seed layer in the case the upper UBM layer 136b comprises copper. FIG. 4E is a cross sectional view of an in-process semiconductor device after attaching a solder ball 191 to the upper UBM layer 136b.

Disclosed aspects can be integrated into a variety of assembly flows to form a variety of different semiconductor devices including WCSP devices and related products. The semiconductor device can comprise single semiconductor die or multiple semiconductor die, such as configurations comprising a plurality of stacked semiconductor die. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, insulated-gate bipolar transistor (IGBT), CMOS, BiCMOS and MEMS.

Those skilled in the art to which this Disclosure relates will appreciate that many variations of disclosed aspects are possible within the scope of the claimed invention, and further additions, deletions, substitutions and modifications may be made to the above-described aspects without departing from the scope of this Disclosure.

1. A semiconductor device, comprising:
a substrate comprising a semiconductor surface layer including circuitry configured for at least one function;
a metal interconnect layer over the semiconductor surface layer comprising a top metal interconnect layer, with a selected one of the metal interconnect layers including an interconnect trace having a first end and a second end, and
a top dielectric layer on the top metal interconnect layer;
a redistribution layer (RDL) on the top dielectric layer, and
a corrosion interruption structure (CIS) including the interconnect trace bridging an interrupting gap in a trace of the RDL.

2. The semiconductor device of claim 1, wherein the semiconductor device comprises a wafer chip-scale package (WCSP).

3. The semiconductor device of claim 1, wherein the CIS further comprises a plurality of metal plugs through a thickness of the top dielectric layer including at a first metal plug connecting to a first end of the interconnect trace and at least a second metal plug connecting to a second end of the interconnect trace for providing a coupling path across the interrupting gap.

4. The semiconductor device of claim 1, further comprising at least one passivation layer on the RDL including at least one passivation aperture.

5. The semiconductor device of claim 4, wherein the RDL includes a plurality of bump pads exposed by ones of the passivation apertures, wherein the RDL further comprises a ground ring positioned on a periphery of the semiconductor device around the plurality of bump pads, and wherein at least one of the coupling paths is within the ground ring.

6. The semiconductor device of claim 5, wherein the ground ring includes at least one of the CIS positioned in a length direction of the ground ring between each of the plurality of bump pads along the periphery of the semiconductor device.

7. The semiconductor device of claim 1, wherein the interconnect trace has a length that is longer than a length of the interrupting gap.

8. The semiconductor device of claim 1, further comprising at least one passivation layer on the RDL including at least one passivation aperture, wherein the passivation layer fills the interrupting gap, and wherein the passivation layer fills the interrupting gap, and wherein the passivation layer is in direct contact with the RDL.

9. The semiconductor device of claim 1, wherein the plurality of metal plugs comprise tungsten plugs that have a minimum area dimension of 0.25 μm to 10 μm.

10. A wafer chip scale package (WCSP), comprising:
a substrate comprising a semiconductor surface layer including silicon configured for at least one function;
at least one metal interconnect layer over the semiconductor surface layer comprising a top metal interconnect layer comprising copper or aluminum including an interconnect trace having a first end and a second end;
a top dielectric layer on the top metal interconnect layer;
a plurality of metal plugs through a thickness of the top dielectric layer including first metal plugs connecting to the first end of the interconnect connect trace and second metal plugs connected to the second end of the interconnect trace;
a redistribution layer (RDL) comprising copper or a copper alloy on the top dielectric layer having an interrupting gap over the interconnect trace;
at least one corrosion interruption structure (CIS) bridging a gap in a trace of the RDL comprising a first side of the RDL connecting to the first metal plugs on the first end of the interconnect trace, and a second side of the RDL connecting to the second metal plugs on the second end of the interconnect trace;
at least one passivation layer on the RDL including at least one passivation aperture; and
wherein the interconnect trace has a length that is longer than a length of the interrupting gap, which together with the first metal plugs and second metal plugs provide a coupling path across the interrupting gap.

11. A method for forming a semiconductor device, comprising:
providing a substrate comprising a semiconductor surface layer including circuitry configured for at least one function including over the semiconductor surface layer and a metal interconnect layers comprising a top metal interconnect layer having at least a top dielectric layer thereon, with a selected one of the metal interconnect layers including an interconnect trace having a first end and a second end;
forming a plurality of metal plugs through a thickness of the top dielectric layer including at least a first metal plug connecting to the first end of the interconnect trace and at least a second metal plug connecting to the second end of the interconnect trace; and
forming a patterned redistribution layer (RDL) on the top dielectric layer including interrupting gap in a trace of the RDL over the interconnect trace to complete a corrosion interruption structure (CIS), wherein a first end of the trace of the RDL is connected by the first metal plug on the first end of the interconnect trace to the first end of the interconnect trace, and wherein a second end of the trace of the RDL is connected by the second metal plug on the second end of the interconnect trace to the second end of the interconnect trace.

12. The method of claim 11, wherein the selected one of the metal interconnect layers comprises the top metal interconnect layer.

13. The method of claim 11, wherein the semiconductor device comprises a wafer chip-scale package (WCSP).

14. The method of claim 11, further comprising forming at least one passivation layer on the RDL including at least one passivation aperture.

15. The method of claim 14, wherein the forming of the RDL includes forming a plurality of bump pads exposed by ones of the passivation apertures, and wherein the coupling path is located relative to the plurality of bump pads at a distance from between 0.25 times to 2 times a center-to-center pitch for the plurality of bump pads.

16. The method of claim 14, wherein the forming of the RDL includes forming a plurality of bump pads exposed by ones of the passivation apertures, further comprises forming a ground ring positioned on a periphery of the semiconductor device around a plurality of bump pads, wherein at least one of the coupling paths is within the ground ring.

17. The method of claim 16, wherein the ground ring includes at least one of the CIS positioned in a length direction of the ground ring between each of the plurality of bump pads along the periphery of the semiconductor device.

18. The method of claim 11, wherein the plurality of metal plugs comprise tungsten plugs that have a minimum area dimension of 0.25 μm to 10 μm.

19. The method of claim 14, wherein the passivation layer fills the interrupting gap.

20. The method of claim 14, wherein the passivation layer is in direct contact with the RDL.

21. The method of claim 14, wherein the forming of the RDL includes forming a plurality of bump pads exposed by ones of the passivation apertures, and wherein a number of the at least one CIS is less than a number of the plurality of bump pads.
